(19) United States
(12) Patent Application Publication
(10) Pub. No.: US 2018/0350648 A1
(43) Pub. Date: Dec. 6, 2018

(54) DEVICE FOR HOLDING, POSITIONING AND MOVING AN OBJECT

(71) Applicant: APPLIED MATERIALS, INC., Santa Clara, CA (US)

(72) Inventor: Christof KLESEN, Modautal-Ernsthofen (DE)

(21) Appl. No.: 15/562,319

(22) PCT Filed: Apr. 1, 2016
(86) PCT No.: PCT/EP2016/057268

§ 371 Date: Sep. 27, 2017

(30) Foreign Application Priority Data
Apr. 9, 2015 (DE) 10 2015 004 582.2

(51) Int. Cl. H01L 21/68; F16C 32/04; H02K 7/09; H02K 41/03; C23C 14/50; C23C 16/458

(52) U.S. Cl. CPC H01L 21/68; F16C 32/0474; H02K 7/09; H02K 2201/18; C23C 14/50; C23C 16/4586; H02K 41/031

(57) ABSTRACT

The present invention relates to a device for holding, positioning and/or moving an object, with a base and with a carrier movable relative to the base, at least one magnetic bearing for generating a bearing or holding force between the base and the carrier, wherein the carrier is contactlessly supported on the base via the magnetic bearing, at least one drive acting contactlessly between base and carrier for the displacement of the carrier along the base in at least one transport direction, wherein the drive comprises a linear motor with at least one slider and one stator, which are arranged on the base and on the carrier and which, aside from a displacement force acting along the transport direction, are configured to create a counter-force between base and carrier which counteracts the bearing or holding force.

### BACKGROUND

### Field

The present invention relates to a device for holding, positioning and/or moving an object, in particular substrates.

For the processing of substrates for the production of semiconductor components, for example for display applications, comparatively large-area substrates have to undergo various surface treatment processes. For example, the surfaces of such substrates have to be treated mechanically or chemically in order for example to form coatings or surface structures on the substrate concerned. Any surface treatment processes have to be carried out under clean room conditions or even in a vacuum, especially when surface treatment steps such as for example sputtering, physical vapour deposition or chemical vapour deposition, possibly also plasma-assisted, have to be carried out.

Since structures in the micrometre or even nanometre range sometimes have to be formed on the substrates, extremely precise positioning of said substrates both in the substrate plane and also normal thereto is required.

The requirements with regard to freedom from particles in the substrate environment make the implementation of a contact-free bearing of the substrate and a corresponding holding, movement or traversing drive necessary. Air bearings are suitable only to a limited extent for high-purity production environments, since undesired air currents can thereby arise in the vicinity of the substrate, which may possibly run counter to complying with required accuracies in the substrate treatment.

Furthermore, there are so-called magnetic wafer stages or magnetic holding or positioning devices with a base and a carrier carrying an object. For the contactless bearing of the carrier on the base, a plurality of magnetic bearings are typically provided each with a distance sensor and a control circuit, which hold the carrier at a predetermined distance from the base in a state of suspension.

A generic wafer stage is known for example from U.S. Pat. No. 7,868,488 B2.

The implementation of actively regulated and correspondingly electrically controllable magnetic bearings especially in a vacuum environment proves to be extremely complex.

Known solutions for the contactless bearing of a carrier for accommodating an object, for example a substrate, which carrier is to be moved along a stationary base, can comprise a plurality of individual or discrete magnetic bearings spaced apart from one another in a transport direction. For the movement of the carrier along a row of magnetic bearings, it is necessary that, during the transport movement of the carrier, the magnetic bearings arranged stationary on the base interact mechanically with the carrier depending on the instantaneous position of the carrier.

A magnetic bearing entering into an operative connection with the carrier at the front in the transport direction has to be activated, while a magnetic bearing lying at the rear end of the carrier in the transport direction has to be correspondingly deactivated. Despite a suitable electrical control for the optional activation and deactivation of individual magnetic bearings entering into the sphere of action of the moved carrier, the emergence of oscillation or resonance phenomena on the carrier cannot be ruled out. Moreover, it is also conceivable for the base also to be subjected to possible externally caused mechanical interfering influences, or for the contactless bearing of the carrier on the base to lead to the excitation of oscillations of the base.

Furthermore, lateral or transverse guidance means also have to be provided for the contactless bearing and for the contactless transport of a carrier along a travel path predetermined by the base. Said guidance means can likewise be implemented by means of suitably configured magnetic bearings. To this extent, at least two types of magnetic bearings often have to be provided along a travel path predetermined by the base, i.e. those magnetic bearings which interact with the carrier in the vertical direction in order to compensate for the weight force of the carrier and further magnetic bearings which function as so-called horizontal magnetic bearings, by means of which a lateral stabilisation or a lateral guidance normal to the transport direction of the carrier can be provided.

A drive also has to be provided for the contactless transport and for the contactless movement of the carrier along the base. Said drive can typically be provided in the form of a linear motor.

It is an aim of the present invention to provide a device for the contactless holding, positioning and/or movement of an object, which is advantageous in terms of control technology and which provides an improved lateral stabilisation for the movement of the carrier. Moreover, it is an objective of the invention to provide an advantageous and improved arrangement of laterally stabilising magnetic bearings, which lie outside an edge region of the carrier movable in the transport direction, so that a two-dimensional movement of the carrier on the base can in principle be enabled. Furthermore, the device should be characterised by a particularly compact structure. In addition, the magnetic bearings provided for the contactless transport of the carrier should be able to be used in a particularly effective and multi-functional manner.

### SUMMARY

### Invention And Advantageous Embodiments

This problem is solved with a device according to claim 1. Advantageous embodiments are the subject-matter of dependent claims.

The device provided in this regard is suitable for the contactless holding, positioning and movement of an object. The device comprises a stationary or fixed base and at least one carrier for the object, said carrier being movable relative to the base. For the contactless support or for the contactless transport and movement of the carrier along the base, at least one magnetic bearing is provided to generate a bearing or holding force between the base and the carrier. The carrier is thereby supported contactlessly on the base via the magnetic bearing. A drive acting in a contactless manner between the base and the carrier is also provided for displacing the carrier along the base in at least one transport direction.

The drive comprises in particular a linear motor with at least one stator and one moving member (herein also referred to as a slider), which are arranged on the base and on the carrier and which, apart from a displacement force acting along the transport direction, are configured to create a further force between the base and the carrier, namely a counter-force counteracting the bearing or holding force. The linear motor for moving the carrier along the base therefore generates not only a displacement force in a movement or in a transport direction, but in addition also a counter-force, which counteracts the at least one magnetic bearing.

If the magnetic bearing is configured for example as a vertical magnetic bearing for the weight force compensation and for the suspended contactless holding of the carrier, then the drive, or the linear motor of the drive, generates a counter-force directed in the direction of the weight force of the carrier. An improved transverse stabilisation for the carrier can thus be achieved. Since the force arising from the drive also acts on the carrier in addition to the weight force, a bearing or holding force arising from the magnetic bearing must be correspondingly increased for a contactless bearing. For a contactless bearing in respect of the vertical direction, care must be taken to ensure that the holding force arising from the magnetic bearing is approximately just as great in terms of magnitude as the sum of the weight force of the carrier and the counter-force arising from the drive.

An increase in the counter-force and holding force may admittedly appear unwise at first sight. However, a better transverse stabilisation of the carrier on the holder can thus be achieved. Resonance frequencies of the bearing of the carrier on the base can thus be changed, in particular increased and shifted into a frequency range which lies outside a range of relevance in practice. The dynamics of the bearing can also be increased by the counter-force. As a result of providing and generating a counter-force approximately in the direction of the weight force, bearing or holding forces can act on the carrier that are much greater than the acceleration due to gravity.

As a result of this, comparatively large acceleration forces, i.e. greater than 1 g, can act on the carrier for the bearing thereof. Such acceleration forces lead to a particularly direct and, to a considerable degree, dynamic bearing and position stabilisation of the carrier on the base. The susceptibility to interference of the contactless bearing of the carrier on the base with respect to a transverse direction can in this regard be improved, without a separate or additional horizontally acting magnetic bearing being required for this.

In this regard, the requirement profile for a transverse stabilisation or lateral guidance for the carrier on the base can be met far more simply by the counter-force arising from the drive. It is for example conceivable to reduce the number of horizontally acting magnetic bearings to be provided for the lateral stabilisation or to completely dispense with bearings for the lateral stabilisation. At the least, however, the complexity of the work on the control for, for example, horizontally acting magnetic bearings and magnetic bearings provided for the lateral stabilisation or lateral guidance of the carrier can be simplified. Production and operating costs for such devices can thus be reduced.

The counter-force arising from the drive brings about an increased rigidity of the bearing or guidance of the carrier on the base in the transverse direction, i.e. normal to the transport direction predetermined by the base and also normal to the direction of the holding force arising from the magnetic bearing. The increase in the rigidity produced by applying a counter-force can be compared to some extent with a spring bearing, wherein the spring essentially providing the bearing is now provided with a higher spring constant.

According to a further embodiment, the at least one magnetic bearing is configured as an actively controllable magnetic bearing. It comprises an electrically controllable electromagnet interacting magnetically with a counter-piece as well as a distance sensor and an electronic unit coupled therewith. A predetermined relative position of the base and carrier can be adjusted in a targeted manner by the electronic unit, the distance sensor and the electromagnet. The magnetic bearing is typically provided with a control circuit which, on the basis of distance measurement signals ascertained by the distance sensor, controls the electromagnet in such a way that the distance between the distance sensor and the counter-piece remains for the most part constant or within a preset range.

If the force of attraction on the counter-piece arising from the electromagnet leads to the electromagnet and the counter-piece moving closer together, this is detected by the distance sensor. The electronic unit coupled with the distance sensor and the electromagnet can then reduce the current flow through the electromagnet in steps or continuously, so that the required distance between the distance sensor and the counter-piece is adjusted and maintained on the basis of the control.

The distance sensor is preferably arranged in the immediate vicinity of the electromagnet. A minimisation of the distance between the distance sensor and the electromagnet is advantageous especially for increasing the degree of collocation. Each magnetic bearing typically has its own control circuit, comprising an electromagnet, a distance sensor and its own electronic unit. In this way, local distance changes between the base and the carrier in the region of the respective magnetic bearing can be precisely detected and selectively evaluated and individually used for a corresponding control of the electromagnet concerned.

The provision of an individual control circuit for each of a multiplicity of magnetic bearings further makes it possible for control currents or control signals for the electromagnet to be generated and processed locally in the region of the respective magnetic bearing. Cabling requirements between the distance sensor and the electronic unit and also between the electronic unit and the respectively assigned electromagnet can thus be reduced. This can have an advantageous effect on the vacuum compatibility of the entire device. In any event, the device according to the invention can provide a positioning and displacement precision of the carrier relative to the base in the range of several micrometres or even in the sub-micrometre range. The device is typically configured vacuum-compatible; that is to say that it is suitable for operation under vacuum conditions, for example for vacuum processes taking place in a vacuum or under particularly low pressure, such as for example for the coating of substrates.

According to a further embodiment, the device according to the invention comprises a plurality of magnetic bearings, which are typically spaced apart from one another in the transport direction or normal thereto. At least one or several of the magnetic bearings is or are configured as vertical magnetic bearings for generating a vertical holding force counteracting the weight force of the carrier. Via at least one, typically via at least two or three magnetic bearings arranged distributed over the area of the carrier, the weight force of the carrier can be compensated for and the carrier can thus be held suspended and contactless on the base.

The arrangement of the magnetic bearing and the counter-piece can be distributed differently on the carrier and the base. For vacuum applications, it is advantageous to provide the magnetic bearing provided with the electromagnet on the base side and a counter-piece interacting magnetically with the latter on the carrier. For a vertical bearing of the carrier in the transport direction, it is then necessary to provide a plurality of magnetic bearings spaced apart from one another in the transport direction on the base, wherein the spacing of said magnetic bearings in the transport direction must be smaller than the corresponding extension of the carrier or its counter-piece in the transport direction.

The spacing of the vertical magnetic bearings spaced apart from one another in the transport direction is typically selected such that at least two vertical magnetic bearings following one another in the transport direction are always located in the sphere of action with the carrier.

A row of discrete magnetic bearings can thus be arranged in the transport direction on the base. A single row of vertical magnetic bearings extending in the transport direction can be provided here and be sufficient. This is provided especially for a suspended bearing of the carrier on the base. Alternatively, a plurality, as for example two, typically parallel rows of magnetic bearings can also be provided in the transport direction, wherein the rows of magnetic bearings then have a spacing in the transverse direction.

According to a further embodiment, at least one magnetic bearing or at least a plurality of magnetic bearings is/are configured as horizontal magnetic bearings for generating a horizontally acting holding force between the base and the carrier. Horizontal and also vertical magnetic bearings can each comprise their own control circuit in each case with an electromagnet, a distance sensor and an electronic unit. The directions of action of horizontal and vertical magnetic bearings, however, are different. This can be achieved by the suitable arrangement and alignment of electromagnets and counter-pieces which can be magnetically engaged with the latter.

It is in principle conceivable for the horizontal magnetic bearing to be arranged along a guide that laterally borders the carrier, and in particular for a plurality of horizontal magnetic bearings spaced apart from one another in the transport direction to be arranged at said lateral guide and, in the same way as the vertical magnetic bearings, to engage and disengage successively with the carrier in the course of the displacement movement of the carrier.

Since the drive acting between the base and the carrier is configured to create a counter-force counteracting the magnetic bearing and in this regard provides an increased rigidity of the bearing for example in the transverse direction, the requirements on the horizontal magnetic bearings for the lateral guidance or transverse stabilisation of the carrier can be advantageously reduced. In this regard, the drive can to a certain extent contribute to the action of the horizontal magnetic bearings.

The counter-force rising from the drive does not necessarily have to act in the vertical direction. This would always be the case when the drive counteracts the vertically acting holding force of a vertical magnetic bearing. According to an alternative embodiment, it is also conceivable that the counter-force arising from the drive counteracts a horizontally acting holding force of a horizontal magnetic bearing. In this case, the drive could contribute to the vertical stabilisation of the magnetic bearing of the carrier or a horizontal magnetic bearing or a row of horizontal magnetic bearings on one side of the carrier could be replaced by the action of the drive. The operating principle underlying the invention remains the same. The counter-force arising from the drive would act solely in the horizontal direction, and therefore normal to the weight force of the carrier and an object arranged thereon.

According to a further embodiment, the horizontal magnetic bearing comprises at least one electromagnet arranged on the base or on the carrier, which cooperates with the counter-piece arranged on the carrier or on the base for the displacement of the carrier in the transverse direction. The transverse direction extends here, relative to the transport direction, transversely, typically normal to the transport direction and also normal to the vertical direction. For vacuum applications, provision is in particular also made here such that the electromagnet of the horizontal magnetic bearing is arranged on the base side, while the counter-piece interacting magnetically with the electromagnet is arranged on the carrier. Of course, the electromagnet and the counter-piece interacting therewith are arranged facing one another on the base or respectively on the carrier, so that an unhindered magnetic interaction between them is possible.

According to a further embodiment of the horizontal magnetic bearing, the counter-piece on the carrier or the base comprises at least one row of permanent magnets poled in an alternating manner, which are spaced apart from one another in the transverse direction obliquely or normal to the transport direction. The permanent magnets can be configured for example as bar magnets, which are orientated with their longitudinal axis for example in the transverse direction. The electromagnet of the horizontal magnetic bearing can comprise an iron core around which a coil is wound, said iron core having a plurality of legs, one whereof extends through the coil.

The spacing of the legs in the transverse direction is typically somewhat smaller than the spacing of the permanent magnets spaced apart from one another in the transverse direction. The free ends of the legs of the iron core around which at least one coil is wound are directed towards the permanent magnets arranged beside one another in the transverse direction. On account of the interaction of the magnetic field generated by the coil with the magnetic field of the permanent magnets, a resultant Lorentz force arises with a force component in the transverse direction. As a result of changing the energisation of the electromagnets of the horizontal magnetic bearing, the force component in the transverse direction or the transverse force arising from the horizontal bearing can be changed in terms of its magnitude and in its direction.

Such an embodiment in particular makes it possible for the counter-piece cooperating with the horizontal magnetic bearing to be arranged spaced apart from the electromagnet of the magnetic bearing in the vertical direction. This further enables a vertically spaced-apart arrangement of the electromagnet and the counter-piece on the base and on the carrier interacting magnetically therewith. In this way, a horizontal magnetic bearing can be implemented without it being necessary for this purpose to provide a rail or holding fixture for lateral guidance or contactless bearing, said rail or holding fixture being arranged laterally along a travel path of the carrier. The region of the base lying beside the carrier in the transverse direction can in particular be configured for the most part barrier-free.

According to a further embodiment, provision is made such that the horizontal magnetic bearing interacts magnetically with an upper side or a lower side of the carrier. It is advantageous if at least one or a plurality of horizontal magnetic bearings is/are arranged on the base side along a transport direction on said base. They are typically located above the carrier or below the carrier. In particular, the upper side or the lower side of the carrier comprises at least one counter-piece interacting magnetically with the horizontal magnetic bearing. Said counter-piece is accordingly arranged at the upper side or at the lower side of the carrier. In this way, and by reason of the special embodiment and mutual arrangement of the counter-piece and the horizontal magnetic bearing, it is made possible to constitute the lateral region, i.e. the region horizontal or normal to the transport direction of the carrier, for the most part barrier-free. Lateral guide rails, such as are usually provided for generic contactless transport systems, can advantageously be dispensed with.

Provision can in particular be made such that all the horizontal and all the vertical magnetic bearings are arranged together on one and the same base, which is located for example above the carrier. The carrier can in this respect be guided along floating and suspended on the base solely by the magnetic interaction of the horizontal and the vertical magnetic bearings.

According to a further embodiment, provision is generally made such that the at least one magnetic bearing and the drive interact magnetically with mutually opposite sides of the carrier. In said embodiment, provision is made such that the drive is arranged on a side of the carrier lying opposite the horizontal or vertical magnetic bearing. If for example the drive is to generate a vertical counter-force counteracting the vertical holding force, provision is advantageously made such that the drive interacts with a lower side of the carrier, and that the vertical magnetic bearing enters into an operative magnetic connection with an upper side of the carrier. Accordingly, provision can however also be made such that the drive interacts with a left-hand side or outer edge of the carrier, while a horizontal magnetic bearing enters into a magnetic interaction with an opposite right-hand side edge of the carrier.

According to a further embodiment, the base comprises a plurality of magnetic bearings spaced apart from one another in the transport direction or in the transverse direction, which magnetic bearings successively enter magnetically into an operative connection with at least one counter-piece arranged on the carrier for the purpose of moving the carrier along the base in the transport direction or in the transverse direction.

The arrangement of a plurality of magnetic bearings on the base is advantageous for the vacuum compatibility of the device. The waste heat arising through the energisation of the coils of the magnetic bearings can be carried away comparatively well via the stationary or fixed base. Thermal conduction with magnetic bearings arranged stationary can at all events be implemented better and more easily than would be the case with magnetic bearings arranged on the carrier side. The heat transport of a carrier supported contactless in a vacuum is comparatively costly and complex.

Provision can further be made such that pairs of horizontal and vertical magnetic bearings are arranged on the base spaced apart in the transport direction. It is also conceivable for vertical magnetic bearings and/or horizontal magnetic bearings to be arranged on the base spaced apart in the transverse direction. It is thus made possible in principle to move the carrier contactless relative to the base both in the transport direction and also in the transverse direction.

In a development of this, provision is further made such that the base comprises two transport paths running normal or obliquely to one another in the transport direction and in the transverse direction, with a plurality of magnetic bearings in each case, wherein the transport paths adjoin one another in an intersection region. In particular, the main movement direction of the carrier relative to the base can be changed in the intersection regions. Depending on the embodiment of the intersection region, a transport path, running for example in the transport direction, can emerge into a further transport path running in the transverse direction.

It is however also conceivable for one of the transport paths to adjoin another transport path obtusely for the formation of a T-intersection, or for two continuous transport paths simply to intersect in the intersection region. Depending on the specific embodiment of the intersection region, it is conceivable for a carrier moved along the transport direction along a first transport path to experience a change in direction in the intersection region, so that it first follows the first transport path in the transport direction up to reaching the intersection region and is then moved onward in the transverse direction along a second transport path. The implementation of a plurality of transport paths running differently in the horizontal plane and the implementation of intersection regions for coupling different transport paths enables an almost arbitrary two-dimensional moveably of the carrier along different paths. Thus, for example, a plurality of carriers can be guided past one another collision-free in different directions, which can prove to be extremely advantageous for the process steps and production sequences for objects to be treated that can be arranged on the carriers.

According to a further embodiment of the invention, provision is further made such that at least two differently aligned sliders or stators of two linear drives are arranged on the carrier, one whereof is configured for moving the carrier relative to the base in the transport direction and the other whereof is configured for moving the carrier relative to the base in the transverse direction. The components of the drive to be provided on the carrier side, for example the sliders configured as passive elements, can be aligned corresponding to the directions of the transport paths coming into question in each case.

Thus, the carrier comprises for example a slider of a first drive, which is configured to move the carrier along the transport direction and along a first transport path. The carrier can likewise be provided with a further slider of a second drive, which is configured exclusively to move the carrier in the transverse direction, i.e. along a second transport path coinciding therewith.

Provision is in particular made such that only the sliders or stators of one of the two drives arranged on the carrier are simultaneously activated. If the carrier is located in an intersection region, which is also provided at the base side with two differently aligned stators or sliders of two drives, provision is made, for changing the movement direction of the carrier, to deactivate the stators of the one drive in favour of the stators of the other drive, or to exchange the role of the active stators of the two drives.

This must of course also be accompanied by the provision of a corresponding activation and deactivation of the respective magnetic bearings of the different transport paths adjoining at the intersection region.

Similar to the magnetic bearings, it also applies to the drive that all the active components of the drive, in the present case the stator or stators, are arranged fixedly on the base in order to improve the vacuum compatibility of the device, and that the slider interacting magnetically therewith is arranged on the carrier. For other non-vacuum applications, any arrangements of active and passive components of the magnetic bearings, i.e. of electromagnets and counter-pieces, on the base and on the carrier can be provided. The same applies to the passive and active components of the drive, the slider and the stator.

According to a further embodiment, at least two sliders or stators are aligned in parallel with one another and arranged at a predetermined minimum spacing from one another in the transport direction or in the transverse direction. The components of the drive, i.e. the stators or sliders, are in this respect arranged on the carrier interrupted in the transport direction or in the transverse direction. The effect of providing on the carrier two components of the drive aligned in parallel with one another, but arranged at a minimum spacing from one another in the transport direction or in the transverse direction is that components of the drive corresponding thereto on the base side are arranged not continuously, but spaced apart from one another in the transport direction or in the transverse direction.

For example, provision can be made such that a plurality of discrete stators spaced apart from one another in the transport direction are arranged on the base for the displacement of the carrier in the transport direction, and that sliders that can be brought into an operative connection therewith are arranged on the carrier. The base-side stators and also the carrier-side sliders can, viewed in the transport direction, each have a certain minimum spacing from one another. The spacings are selected here in such a way that at least one slider of the carrier is in an operative connection in each case with at least one stator of the base. The extension of the sliders and stators on the carrier and on the base and also their spacings in the transport direction must be selected such that at least one slider of the carrier is always in an operative connection with in each case at least one stator of the base. Such an arrangement can likewise be provided for an alternative embodiment, wherein the stators or the at least one stator are arranged on the carrier side and the sliders or the at least one slider are arranged on the base side.

The provision of a predetermined minimum spacing of the sliders or stators of the drive arranged on the carrier, either in the transport direction or the transverse direction, enables the implementation of an intersection region of two transport paths adjoining one another.

According to a further embodiment of the device, each of the transport paths in the transport direction or in the transverse direction comprises stators or sliders spaced apart from one another. The sliders or stators of one transport path are arranged at the level of the intermediate spaces between the sliders or stators of the respective other transport path. If, for example, a first transport path provided on the base side and extending in the transport direction comprises a row of stators spaced apart at approximately regular intervals in the transport direction, the second transport path provided on the base side can likewise comprise a plurality of stators spaced apart from one another in the transverse direction. An imaginary connecting line of all the stators of the second transport path intersects the first transport path in an intermediate space between the stators of the first transport path and vice versa. In this way, the stators of the first and second transport path can be arranged in one and the same plane collision-free and contactless relative to one another.

In an intersection region of two adjoining or intersecting transport paths, provision can be made such that the intermediate spaces between the sliders or stators of a first and a second transport path essentially come to lie overlapping one another.

According to a further embodiment, provision is made such that, in the intersection region of two transport paths, a pair, corresponding with each other, of sliders and stators of two drives arranged on the carrier and on the base, which pair belongs to one of the transport paths, can be activated in alternation with a pair, corresponding thereto, of sliders and stators of the respective other transport path. In other words, each of the transport paths has its own drive. To this extent, two drives at a time are present in the intersection region, which are configured for the transport of the carrier in different directions. When the carrier is present in the intersection region, only one of the two drives acting in different horizontal directions is activated, while the respective other drive is deactivated.

In a development of this, and according to a further embodiment, at least two magnetic bearings, which are assigned to one of the two transport paths, can be activated in the intersection region, while two further magnetic bearings assigned to another transport path are correspondingly continuously deactivated. This applies in particular to the vertical magnetic bearings. If the first and the second transport path have different vertical magnetic bearings and two different kinds of vertical magnetic bearings are present in the intersection region, it is necessary, for a change in direction of the carrier in the intersection region, to deactivate for example the vertical magnetic bearings of one transport path in favour of the vertical magnetic bearings of the other transport path. The deactivation and activation of vertical magnetic bearings lying in the intersection region takes place in each case continuously and in an opposing manner, so that the carrier does not experience any change in position during the switch-over from vertical magnetic bearings of one transport path to the vertical magnetic bearings of another transport path.

Such a switch-over from vertical magnetic bearings of a first transport path to the vertical magnetic bearings of a second transport path typically takes place when a carrier is at rest. A similar switch-over from horizontal magnetic bearings of one transport path to the horizontal magnetic bearings of another transport path adjoining at the intersection region can take place in a similar manner. The switch-over of the vertical magnetic bearings can take place in a timed and synchronous manner, but also offset in time for the switching-over of the horizontal magnetic bearings in the intersection region.

It is also conceivable that the vertical magnetic bearings arranged in the intersection region equally belong to both adjoining transport paths. No special measures for the vertical magnetic bearings then need to be taken for a change in direction of the carrier in the intersection region. The vertical magnetic bearings of the transport path along which the carrier is just being moved along need to be activated only upon leaving the intersection region.

### BRIEF DESCRIPTION OF THE DRAWINGS

Further aims, features and advantageous embodiments of the invention are explained in the following description of examples of embodiment making reference to the figures. In the figures:

FIG. 1 shows a diagrammatic representation of a magnetic bearing provided with a control circuit,

FIG. 2 shows a diagrammatic representation of the functional principle of the device according to the invention with a drive, which apart from a driving force also generates a counter-force counteracting the bearing or holding force of the magnetic bearing,

FIG. 3 shows a development of the example of embodiment shown in FIG. 2 with two horizontal magnetic bearings,

FIG. 4 shows a further embodiment with two vertical magnetic bearings horizontally spaced apart, a horizontal magnetic bearing and with a drive arranged opposite the horizontal magnetic bearing,

FIG. 5 shows a further embodiment of the device according to the invention, wherein the horizontal magnetic bearing is arranged outside the carrier,

FIG. 6 shows a diagrammatic cross-sectional representation of the drive constituted as a linear motor,

FIG. 7 shows a plan view of a slider of a horizontal magnetic bearing,

FIG. 8 shows a cross-section through an embodiment of a horizontal magnetic bearing,

FIG. 9 shows a plan view of the device according to the invention with a base elongated in the transport direction,

FIG. 10 shows a diagrammatic representation of the sliders of two drives acting in different directions, said sliders being arranged at the underside of the carrier,

FIG. 11 shows a plan view of two different kinds of counter-pieces at the upper side of the carrier, which cooperate with horizontal magnetic bearings acting in different horizontal directions,

FIG. 12 shows a diagrammatic representation of two transport paths running at right angles to one another with a carrier located in an intersection region,

FIG. 13 shows a diagrammatic representation of a configuration of transport paths and traversing or displacement directions for the carrier resulting therefrom and

FIG. 14 shows a further embodiment of different transport paths together with traversing or displacement possibilities resulting therefrom for the carrier supported contactless on the base.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

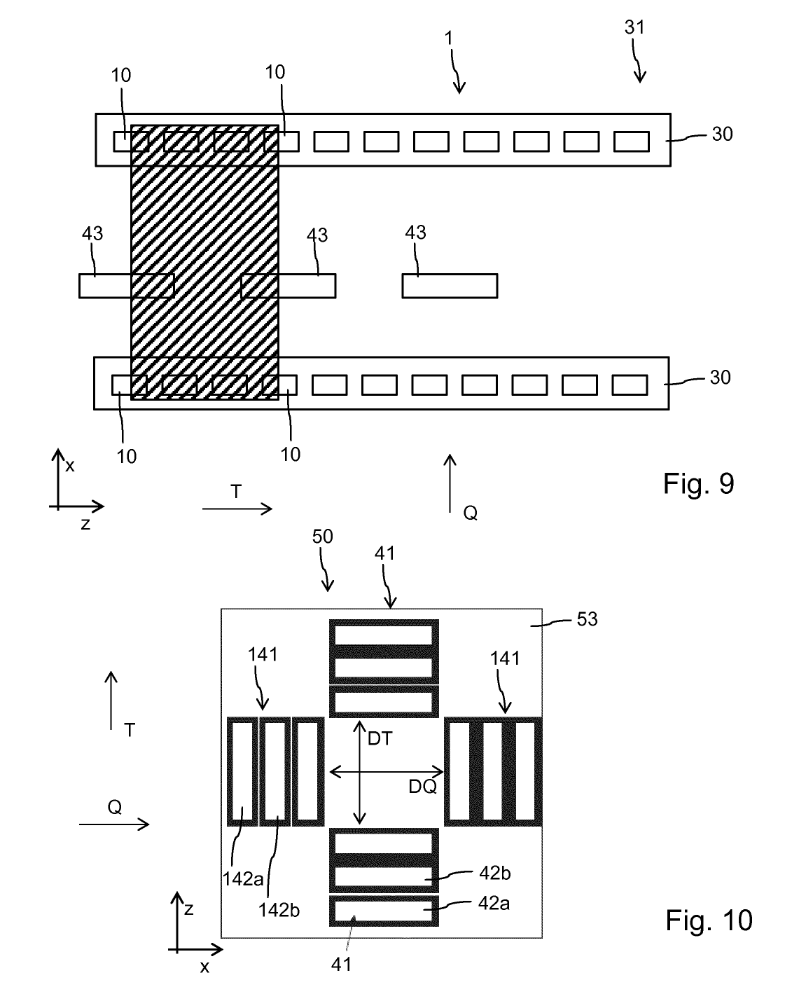

FIGS. 4 and 9 show in a simplified and diagrammatic representation a device 1 according to the invention for holding, positioning and/or moving an object 52, which is arranged on a carrier 50. Device 1 can be configured for example as a wafer stage or as a transport system for the vacuum coating of displays. Device 1 comprises a fixed base 30, in the present case in the form of at least two guide rails, which extend in the representation according to FIG. 9 in transport direction (T) or in the z-direction.

For the contactless bearing and for the contactless transport of carrier 50 on base 30, a plurality of magnetic bearings 10 spaced apart from one another in the transport direction and aligned in the transport direction and lying behind one another in a row are provided in transport direction (T) on the base 30. Magnetic bearings 10 provided in the present case at the, related to the transport direction (T), left-hand and right-hand lateral edges of carrier 50 serve for the contactless bearing of carrier 50 on the stationary or fixed base 30.

Furthermore, a plurality of discrete stators 43 of a drive 40 are arranged on the base 30 also in transport direction (T), which cooperate contactlessly with at least one slider 41 corresponding thereto on the carrier 50 in the manner of a linear motor 38. A linear motor 38 can be formed by base-side stators 43 and at least one or more carrier-side moving members (“sliders 41”), which linear motor exerts a displacement force (V) directed in the transport direction on carrier 50 during the operation of device 1. In this way, carrier 50 can be supported contactlessly on the base 30 and can also be moved contactless along the base.

The fundamental structure of a magnetic bearing 10 is shown in the cross-section of FIG. 2. The magnetic bearing 10 is arranged on the base side, i.e. on the stationary base 30. It comprises at least one electromagnet 12 with a coil 16 and with an iron core 14 or ferrite core. The free ends of the legs of iron core 14 constituted horseshoe-shaped are facing carrier 50. On the carrier 50, a counter-piece 18 interacting magnetically with the electromagnet 12 is arranged facing the magnetic bearing 10. The magnetic bearing 10 further comprises a distance sensor 20, which measures a distance 26 between the carrier 50 and the magnetic bearing 10 arranged on the base side. The counter-piece 18 can be constituted ferromagnetic or permanent-magnetic. It typically extends parallel to the base 30 or parallel to guide rails (not explicitly shown) of the base 30, along which the carrier 50 can be displaced in a contactless manner.

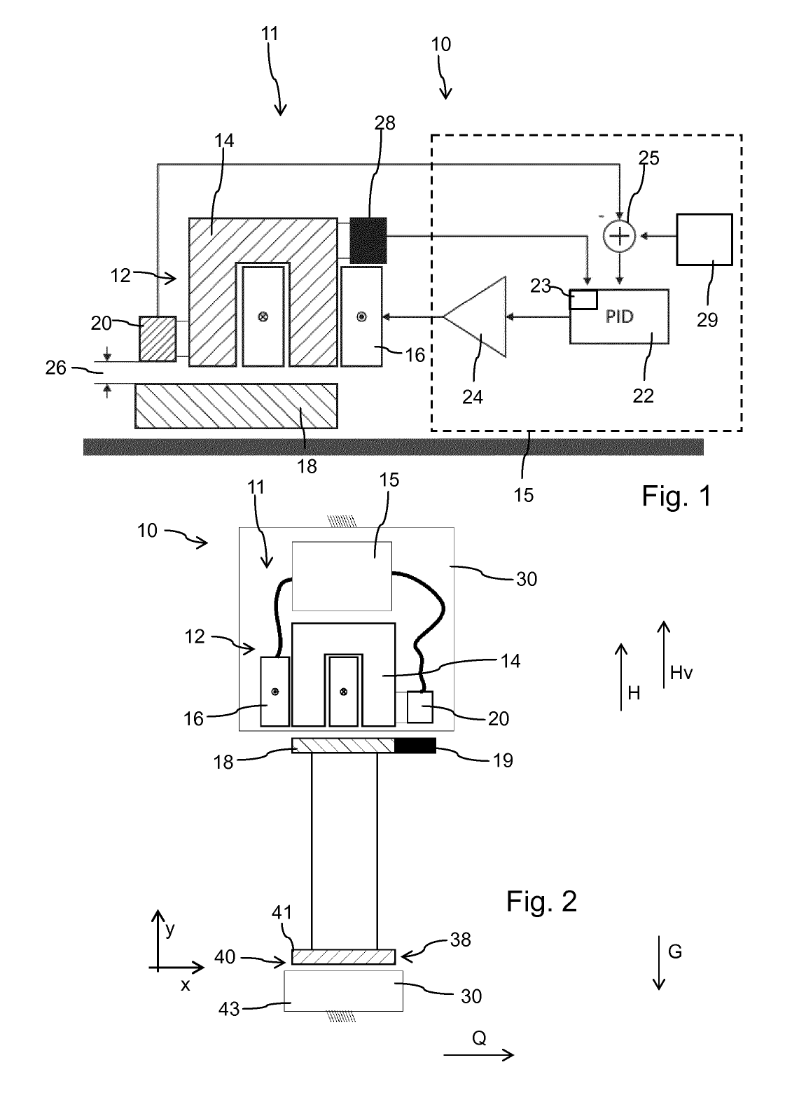

Distance sensor 20, electromagnet 12 and electronic unit 15 form a control circuit 11, which is shown separately and somewhat detailed in FIG. 1. Apart from distance sensor 26, control circuit 11 also comprises a setpoint generator 25, a controller 22, an amplifier 24 and electromagnet 12 acting as an electromagnetic stator. Instead of an electromagnet 12, other electromagnetic stators, for example bi-directionally acting Lorentz or plunger-coil stators, can in principle also be used for all magnetic bearings 10, 100, 200.

Control signals that can be generated by controller 22 are amplified by the amplifier 24 and accordingly fed to coil 16 to generate a holding force (H) acting on counter-piece 18. Distance sensor 20 is preferably arranged in the immediate vicinity of electromagnet 12 or the electromagnetic stator, said distance sensor permanently measuring a distance 26 from counter-piece 18 or carrier 50. Distance 26 determined by distance sensor 20 is fed in the form of a distance signal to setpoint generator 25. The setpoint value and the actual value are compared with one another in setpoint generator 25. Corresponding to the difference between the setpoint value and the actual value, a corresponding comparison signal is fed to controller 22, which generates therefrom a control signal provided for controlling electromagnet 12 and feeds said control signal to amplifier 24.

The amplified control signal fed to coil 16 is calculated and determined in such a way that a predetermined distance 26 between carrier 50 and base 30 is maintained, and that, in the event of deviations from the required distance, the force arising from the electromagnetic stator or electromagnet 12 for maintaining distance 26 is adapted dynamically.

The electronic components of magnetic bearing 10 are typically combined in a single electronic unit 15. All the electronic components, such as for example amplifier 24, controller 22 and setpoint generator 25, can at least be accommodated on a common printed circuit board, for example in the form of a single integrated switching circuit. The space requirement for the electronic unit and an accompanying cabling requirement can in this respect be reduced to a minimum.

Control circuit 11 can optionally also be provided with an acceleration or movement sensor 28 configured to determine excitation of oscillations of the base 30. The signals that can be generated by movement sensor 28 are typically fed to an oscillation damper 23, which can be integrated for example in controller 22. With a control 29 coupled with the setpoint generator 25, different required distances 26 between base 30 and carrier 50 can be adjusted in a targeted manner and as required.

A reference portion 19 can also be arranged on carrier 50, which is facing the distance sensor 20, and which, roughly related to transverse direction (Q), is arranged approximately overlapping, but at a vertical distance from, distance sensor 20 on carrier 50.

Magnetic bearing 10 represented diagrammatically in FIGS. 1 and 2 is configured as a vertical magnetic bearing. It generates a holding force (H), in particular a vertical holding force (Hv), which at least compensates for or applies the weight force of carrier 50 and an object 52 arranged thereon.

In the example of embodiment shown in FIGS. 2, 3 and 5, a drive 40 in the form of a linear motor 38 is provided at the underside of carrier 50. Linear motor 38 comprises here at least one or more sliders 41 arranged on carrier 50, which cooperate with stators 43 corresponding thereto, said stators being arranged on base 30, for the purpose of moving carrier 50 in transport direction (T). The specific geometrical shape of base 30 is not shown in the present case. It goes without saying that the components of the drive arranged on the base side, i.e. stators 43 and also magnetic bearings 10, are arranged stationary and immobile relative to one another along transport path 31 predetermined by base 30.

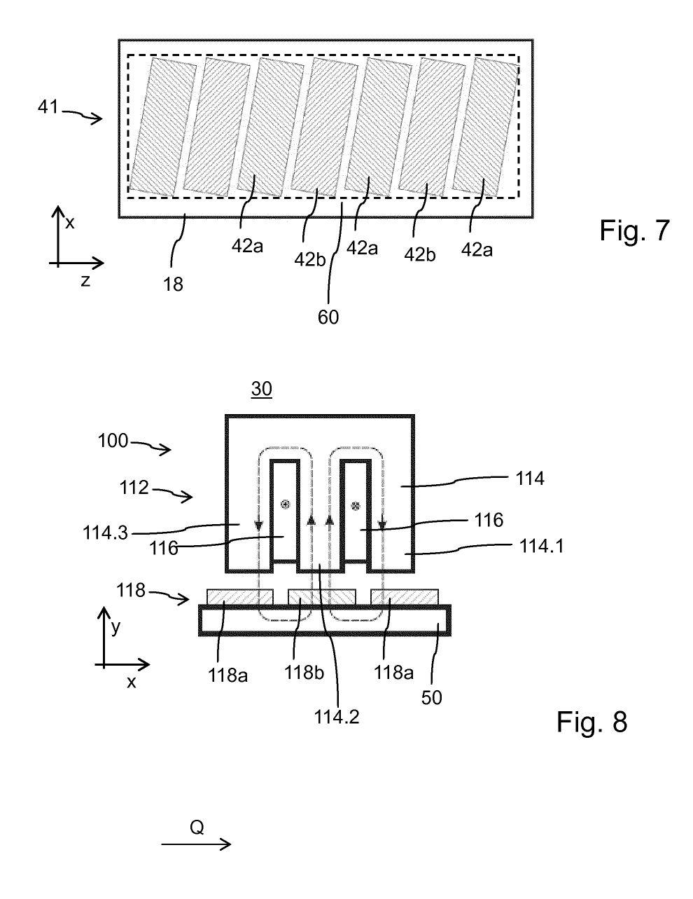

The structure of drive 40 is shown diagrammatically in FIGS. 6 and 7. Drive 40 provided in the manner of a linear motor 38 comprises permanent magnets 42a, 42b with alternating polarity arranged at regular intervals in transport direction (T) on carrier 50. Permanent magnet 42a is poled in the opposite direction to adjacent permanent magnet 42b. Permanent magnet 42a following the latter in the transport direction is poled in the same direction as the last but one permanent magnet 42a. The regular arrangement of magnets 42a, 42b poled in an alternating manner on carrier 50 forms an elongated slider 41, which can cooperate with an electrically controllable stator 43, which is arranged on base 30.

Stator 43 comprises an iron or ferrite core 44 provided with a plurality of legs, wherein a coil 45, 46, 47 is wound round every second or next but one leg in transport direction (T). Coils 45, 46, 47 form the three phases of stator 43 and an electric current can be applied to them alternately. The periodicity or the centre-to-centre distance of individual equidistantly arranged legs 44.1, 44.2, 44.3, 44.4, 44.5, 44.6 and 44.7 of iron core 44 is somewhat smaller than the centre-to-centre distance or the periodicity of permanent magnets 42a, 42b, 42a, 42b arranged in an alternating manner in transport direction (T). By alternately applying an electric current to individual coils 45, 46, 47, a displacement force (V) acting in transport direction (T) can thus be exerted on carrier 50 relative to base 30.

The use of permanent magnets 42a, 42b, which are typically arranged on a steel plate of carrier 50, in combination with slider 43 leads to an attractive counter-force (G) also being exerted on carrier 50 aside from a displacement force (V) in transport direction (T), said counter-force pointing vertically downwards in the examples of embodiment of FIGS. 2, 3 and 5. Drive 40 thus performs a dual function. On the one hand, it generates a displacement force (V) for moving carrier 50 in transport direction (T). On the other hand it generates a counter-Force (G) counteracting the holding force (H) of magnetic bearing 10. In this way, drive 40 can contribute to an improved transverse stabilisation of carrier 50 with respect to a transverse direction (Q), i.e. especially when counter-force (G) acts at right angles or obliquely to the holding force (H) of magnetic bearing 10.

It can be seen in the plan view according to FIG. 7 that permanent magnets 42a, 42b of slider 41 of linear motor 38, relative to transport direction (T), are not aligned exactly vertical, i.e. in the x-direction, but rather at a certain angle of inclination to the x-direction or transverse direction (Q). Slider 43, i.e. its iron core 44, can on the other hand be aligned corresponding to a rectangular imaginary outer contour 60 formed by permanent magnets 42a, 42b. The orientation of permanent magnets 42a, 42b inclined slightly with respect to transverse direction (Q) ensures that, when there is a translation movement of slider 41 with respect to stator 43, a counter-force (G) that is as homogeneous and constant as possible is generated. In terms of control technology, this proves to be advantageous for magnetic bearing or bearings 10, 100 lying opposite drive 40 during a movement of carrier 50 in transport direction (T).

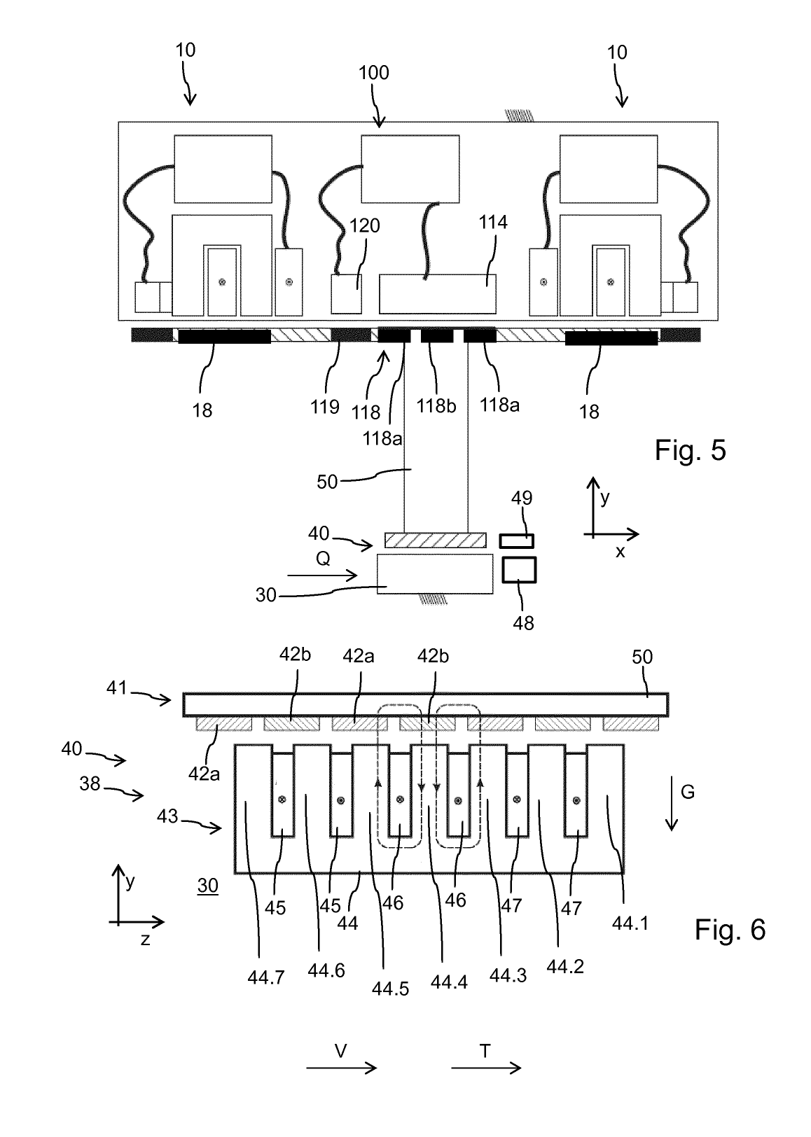

Furthermore, and independently of the specific embodiment of slider 41 and stator 43 of drive 40, drive 40 can also, as shown in FIG. 5, be provided with a position sensor 48 and with a coding 49 corresponding thereto on the base and on carrier 50. Coding 49 extends in transport direction (T). It is preferably arranged on carrier 50 directly opposite a position sensor 48 corresponding thereto, said position sensor typically being located in the immediate vicinity of stators 43 of drive 40. The given actual position of carrier 50 in transport direction (T) can be determined with the coding 49 and the position sensor 48.

Any disturbances or disturbing forces acting laterally on the carrier can be compensated for much more easily by counter-force (G) acting for example downwards in the vertical direction on carrier 50. As a result of providing a counter-force (G) arising from drive 40, any disturbing influences occurring in the horizontal direction and in transverse direction (Q) have much smaller effects on an undesired movement of carrier 50 in transverse direction (Q).

This also has the advantage that the outlay for a lateral or transverse stabilisation for carrier 50 supported contactless on base 30 can be reduced. This enables a far more compact design and possibly also a more cost-effective implementation of device 1.

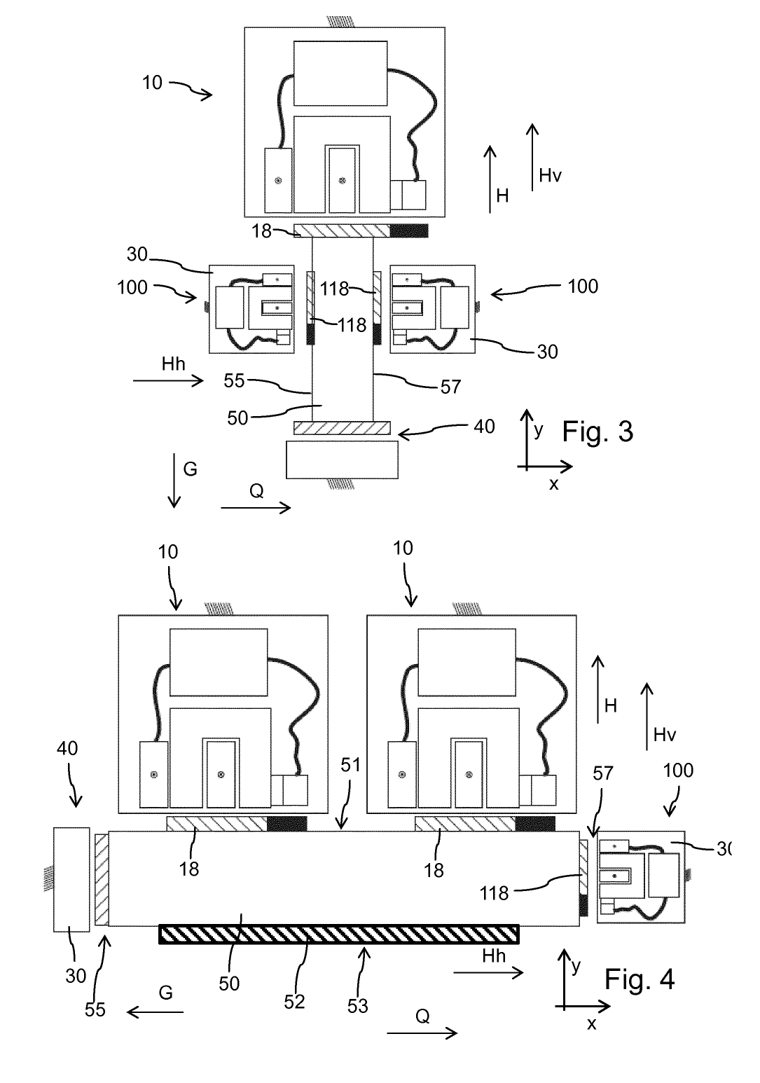

In FIG. 3, as a supplement to FIG. 2, two magnetic bearings 100 arranged at the left-hand and right-hand lateral edges of carrier 50 are provided. These bearings 100 are also arranged fixedly on base 30. They each cooperate with a lateral counter-piece 118 facing them, the latter in each being arranged at opposite sides of carrier 50 facing respective magnetic bearing 100. The mode of action and the structure of magnetic bearing 100 can be essentially identical or similar to that of magnetic bearing 10. Similar to the vertical bearing of carrier 50 via magnetic bearing 10 arranged above carrier 50, a lateral guidance or a transverse stabilisation of carrier 50 in transverse direction (Q) can take place via magnetic bearings 100 arranged at opposite sides of carrier 50. Although a row of horizontal magnetic bearings 100 provided for the lateral stabilisation is not explicitly shown in FIG. 9, they extend more or less in the same way as vertical magnetic bearings 100 represented there.

A plurality of horizontal magnetic bearings 100 spaced apart from one another in transport direction (T) are provided at the two opposite sides, in the present case both at left-hand side 55 and also at right-hand side 57, of carrier 50 for a lateral guidance of carrier 50. In the embodiment shown here in the present case with electromagnets 12, which can exert only an attractive force on carrier 50 or on its counter-pieces 118, a guidance of carrier 50 in transverse direction (Q) therefore requires horizontal magnetic bearings 100 arranged on both sides of carrier 50.

In the further embodiment according to FIG. 4, a horizontal magnetic bearing 100 is provided only on right-hand side 57 of carrier 50, while drive 40 is arranged at opposite left-hand side 55. In this example of embodiment, two vertical magnetic bearings 10 spaced apart from one another in transverse direction (Q) are also provided above carrier 50. Object 52 to be held on the carrier is located at underside 53 of carrier 50. In this example of embodiment of device 1, drive 40 generates a counter-force (G) acting in the horizontal direction, which counteracts the lateral holding force (Hh) of horizontal magnetic bearing 100 lying opposite.

For example, the mode of action of horizontal magnetic bearing 100 arranged at left-hand side 55 of carrier 50 in FIG. 3 can thus be completely replaced by drive 40. The saving of one of horizontal magnetic bearings 100 ultimately results through the arrangement shown in FIG. 4 and through the dual function of drive 40. The replacement of a horizontal magnetic bearing 100 by drive 40 arranged laterally along carrier 50 brings a considerable saving potential.

It should further be noted in this regard that FIGS. 2, 3, 4 and 5 can only reproduce by way of example a cross-section through the device shown diagrammatically in FIG. 9, and that all magnetic bearings 10, 100 shown in cross-section and drive components slider 41 and stator 43 are arranged in a regular or recurrently equidistant manner in transport direction (T), i.e. perpendicular to the plane of the paper of FIGS. 2, 3, 4.

The arrangement of two rows of individual magnetic bearings 10 running in parallel and spaced apart from one another in transverse direction (Q), as represented in FIGS. 9 and 12, does not necessarily have to be provided. For a vertical magnetic bearing, it is in principle sufficient if only a single vertical magnetic bearing 10 is provided in transverse direction (Q) and if a plurality of such magnetic bearings 10 are arranged in a row in transport direction (T), as is shown diagrammatically for example in FIGS. 2 and 3. In such an embodiment, carrier 50 is supported in a suspended manner virtually only pointwise on base 30. Any oscillations or swinging movements of carrier 50 in transverse direction (Q) can be compensated for or at least damped by the counter-force (G) arising from linear drive 38.

A further embodiment of a horizontal magnetic bearing 100 is shown in FIGS. 5 and 8. The latter comprises, in the same way as linear drive 38, an iron or ferrite core 114 provided with a plurality of legs 144.1, 144.2 and 144.3. A coil 116 is wound round a central leg 144.2. To that extent, iron core 114 and coil 116 form an electromagnet 112 which, like stator 43 of linear motor 38, cooperates with a counter-piece 118. Counter-piece 118 comprises, in the same way as slider 41, a plurality of, in the present case at least two or at least three, alternatingly polarised permanent magnets 118a, 118b, 118a, which in the embodiment shown in FIGS. 5 and 8 are arranged on carrier 50 spaced apart from one another in transverse direction (Q).

As described previously in respect of linear motor 38, a force directed in transverse direction (Q) from base 30 onto carrier 50 can be exerted by applying an electric current to coil 116. Horizontal magnetic bearing 100 shown in FIG. 8 differs in this respect from vertical magnetic bearing 10 not only with regard to its arrangement and mode of action, but also with regard to its structure.

The variant of embodiment of a horizontal magnetic bearing 100 shown in FIGS. 5 and 8 is advantageous in that magnetic bearing 100 acting in the horizontal direction or in transverse direction (Q) can also be arranged outside the lateral region of carrier 50 and thus for example above carrier 50. For example, horizontal magnetic bearing 100 can be arranged on the base between two vertical magnetic bearings spaced apart from one another in transverse direction (Q). Horizontal magnetic bearing 100 can also be provided with a position sensor 120, which can cooperate with a reference portion 119 arranged opposite on carrier 50 for the determination of the position in transverse direction (Q). Position sensor 120 as well as distance sensors 20 measuring in the vertical direction can be implemented optically, capacitively or also magnetically.

The embodiment of horizontal magnetic bearing 100 shown in FIG. 8 can admittedly bring about only comparatively little travel or a comparatively small movement of carrier 50 in transverse direction (Q). On account of counter-force (G) arising from drive 40, which in the example of embodiment according to FIG. 5 acts against vertical holding force (Hv) of the two vertical magnetic bearings 10, such a small displacement of carrier 50 in transverse direction (Q) by the horizontal magnetic bearing 100 may already be sufficient.

The embodiment according to FIG. 5 is advantageous in that no structural measures at the side of carrier 50 need to be provided for the transverse stabilisation and for the lateral guidance of carrier 50 in respect of transverse direction (Q). The freedom from barriers, so to speak, prevails to the left and right of carrier 50, so that, as a result of the bearing proposed here, the possibilities in principle for the moveability of the carrier both in transport direction (T) and also in transverse direction (Q) are now in principle provided.

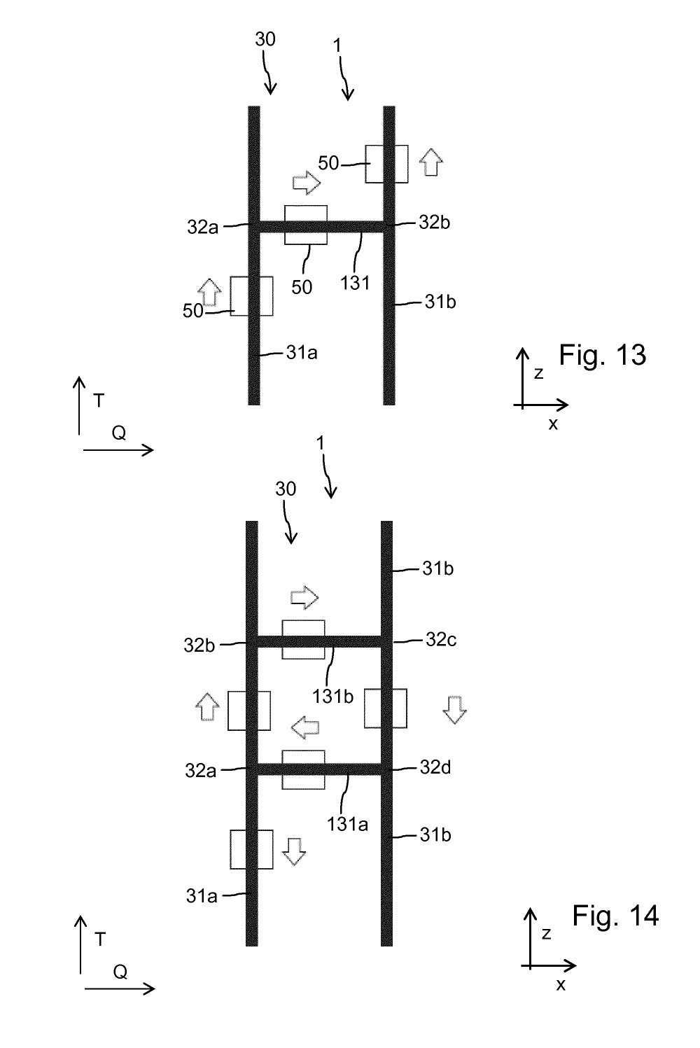

Finally, the base can thus provide a plurality of differently orientated transport paths 31, 131, along which magnetic bearings 10, 100 provided for the corresponding movement of carrier 50 are arranged. For example, the most diverse transport paths 31 and 131, as shown in FIGS. 13 and 14, are conceivable, wherein transport paths 31 extend in transport direction (T) and transport paths 131 extend in transverse direction (Q). Transport paths 31, 131 are typically orientated as right angles to one another in the horizontal plane. In this regard, FIGS. 13 and 14 show a plan view from above.

Individual transport paths 31, 131 do not necessarily have to comprise two parallel rows of magnetic bearings 10 spaced apart in transport direction (T) or transverse direction (Q), as is shown for example in FIG. 9. A transport path 31 can in principle also be formed by an individual bearing rail with only a single row of discrete magnetic bearings 10 spaced apart from one another in transport direction (T) or transverse direction (Q), as is indicated for example in FIG. 2 or FIG. 3. A single-row vertical bearing is suitable in particular for a suspended arrangement and bearing of carrier 50 on base 30.

A left-hand transport path 31a is shown in FIG. 13, which extends in transport direction (T), and which in an intersection region 32a adjoins a further transport path 131 running at right angles thereto. Located at an end of transport path 131 facing away from intersection region 32a is a further intersection region 32b, in which transport path 131 again changes over into a further transport path 31b extending in transport direction (T).

In the embodiment according to FIG. 14, the two parallel transport paths 31a, 31b spaced apart from one another in transverse direction (Q) are connected to one another by two transport paths 131a, 131b spaced apart from one another in transport direction (T). A total of four intersection regions 32a, 32b, 32c, 32d results. Accordingly, a carrier 50 can be moved almost arbitrarily between intersection regions 32a, 32b, 32c, 32d along one of transport paths 31a, 31b, 131a, 131b in each case.

In FIG. 12, one of intersection regions 32 is represented somewhat enlarged, but diagrammatically simplified. Thus, a plurality of stators 43 of drive 40 spaced apart from one another in transport direction (T) are arranged on base 30 along a transport path 31 extending in transport direction (T), which stators each cooperate with sliders 41 of carrier 50 provided correspondingly at underside 53 of carrier 50. Intermediate spaces 3 are provided between individual stators 43 arranged on the base side. Two transport paths 31, 131 orientated at right angles to one another intersect in intersection region 32, wherein second transport path 131 runs in transverse direction (Q).

Transport path 131 is also provided on the carrier side with stators 143 of a further drive 140. Intermediate spaces 103 are also provided between stators 143 of further drive 140, which stators are arranged offset and spaced apart in transverse direction (Q). Individual stators 43, 143 of the two drives 40, 140 are arranged in intersection region 32 in such a way that an imaginary connecting line of all stators 43 of first transport path 31 runs in an intermediate space 103 between two stators 143 of drive 140 which follow one another in transverse direction (Q).

Conversely, provision is also made such that an imaginary connecting line of all stators 143 of drive 140 runs through an intermediate space 3 between stators 43 of drive 40 which are adjacent in transport direction (T).

In the centre of intersection region 32, intermediate spaces 3, 103 of the two transport paths 31, 131 possibly come to lie overlapping at least in sections.

Corresponding to the orientation and arrangement of stators 43, 143 of the two drives 40, 140, corresponding sliders 41, 141 are provided at the underside of carrier 50, which sliders each comprise previously described permanent magnets 42a, 42b and 142a, 142b arranged in an alternating manner. The orientation of permanent magnets 42a, 42b of slider 41 is rotated through 90° with respect to the orientation of permanent magnets 142a, 142b of slider 141 of drive 140. In addition, sliders 41, 141 are arranged beside one another and free from overlap at underside 53 of carrier 50.

At least two sliders 41 of a drive 40 should be arranged spaced apart from one another at underside 53 of carrier 50. Two sliders 141 of a drive 140 are arranged on carrier 50 spaced apart from one another at a minimum distance DQ in transverse direction (Q). The same applies to sliders 41 of other drive 40 lying in parallel with one another. The latter are arranged on carrier 50 spaced apart from one another by a minimum distance DT in transport direction (T).

In this way, a configuration in intersection region 32 indicated diagrammatically in FIG. 12 can be obtained, wherein sliders and stators 41, 43 of a drive 40 and also stators and sliders 141, 143 of other drive 140 come to lie geometrically overlapping one another. In order that carrier 50 arrives in intersection region 32 coming for example from the left from transverse direction (Q), an activation of stators 143 of drive 140 is required, which runs along second transport path 131. Upon reaching a position in intersection region 32, drive 140 can be stopped. Stators 143 of drive 140 can then be deactivated and stators 43 of other drive 40 can be activated. Carrier 50, proceeding from intersection region 32, can thus be moved along first transport path 31.

It goes without saying that, corresponding to FIG. 9, transport paths 31, 131 are each also provided with a row of a vertical magnetic bearings 10, which are arranged on the base at regular intervals along respective transport paths 31, 131 and are activated as required corresponding to the movement of carrier 50 relative to the base.

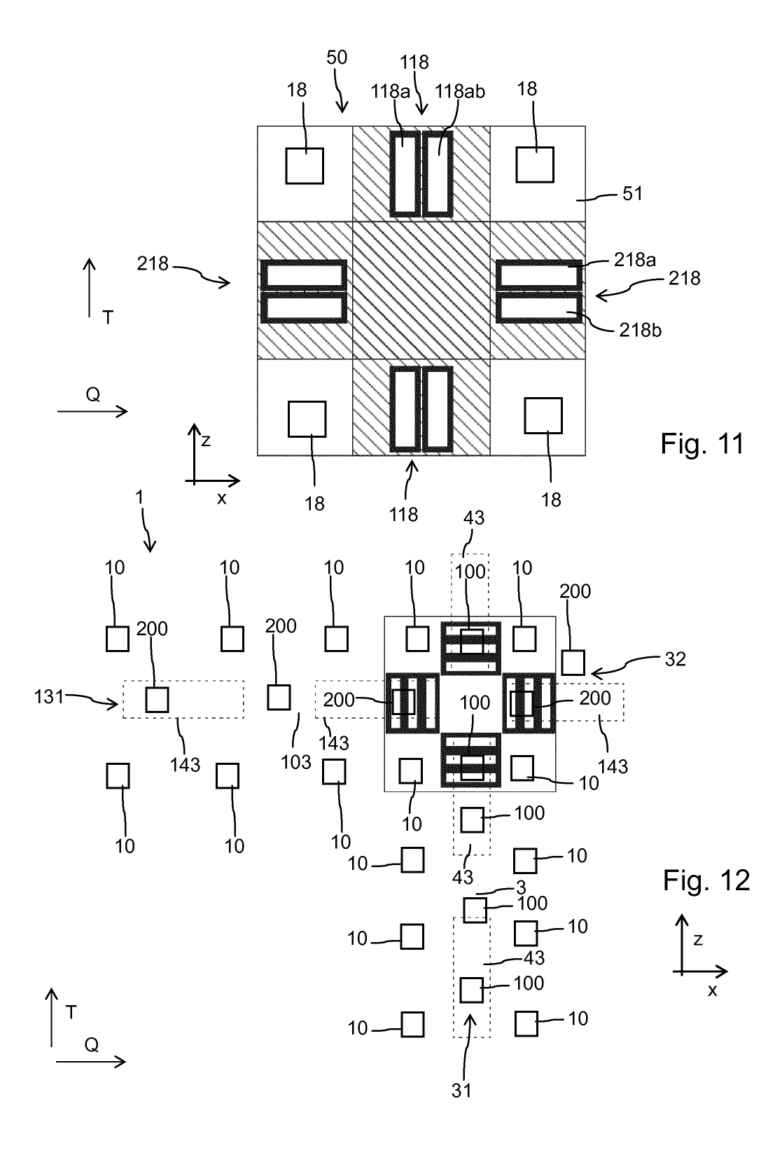

Finally, FIG. 11 also shows by way of example that individual counter-pieces 118, 218 of two different horizontal magnetic bearings 100, 200 are arranged at upper side 51 of carrier 50. Counter-pieces 118 spaced apart from one another on carrier 50 in transport direction (T) each comprise two or more permanent magnets 118a, 118b, which are spaced apart from one another in transverse direction (Q) and the longitudinal alignment whereof runs essentially parallel to transport direction (T). The two counter-pieces 118 arranged on carrier 50 at the front and at the rear in transport direction (T) each cooperate with horizontal magnetic bearings 100, which are arranged on base 30 at regular intervals in transport direction (T), and which can provide a horizontal holding force (Hh) exerted on carrier 50 in transverse direction (Q).

The two further counter-pieces 218 arranged on carrier 50 at the front and at the rear in transverse direction (Q), on the other hand, cooperate with horizontal magnetic bearings 200, which are arranged on base 30 spaced apart at regular intervals in transverse direction (Q) along transport path 131, and which can provide a holding force (Hh) acting on the carrier in transport direction (T). Accordingly, permanent magnets 118a, 118b are arranged on carrier 50 also rotated through 90° with respect to permanent magnets 218a, 218b of counter-pieces 218. Counter-pieces 118, 218, which in the present case are arranged at upper side 51 of the carrier, can, in the same way as sliders 41, 141 provided at the underside, come to lie geometrically overlapping with corresponding horizontal magnetic bearings 100, 200 in the intersection region of two transport paths 31, 131.

Insofar as a change in direction is provided for carrier 50, horizontal magnetic bearings 100 assigned to transport path 31 for example have to be deactivated, while horizontal magnetic bearings 200 assigned to other transport path 131 have to be activated.

The same is of course also to be provided for vertical magnetic bearings 10. If vertical magnetic bearings 10 of the one transport path 31 are configured for the most part identical to those of the other transport path 131, it may however be sufficient twice if double the number of vertical magnetic bearings 10 of the two transport paths 31, 131 is not provided in intersection region 32 itself. In the course of a change in direction of the movement of the carrier in intersection region 52, it may be sufficient if only vertical magnetic bearings 10 of first and/or second transport path 31, 131 are always activated as required as soon as carrier 50 leaves intersection region 32 and arrives in the area of action of magnetic bearings 10, which belong solely to one of transport paths 31, 131.

What is claimed is:

1. A device for holding, positioning and/or moving an object (52), with
a base (30) and with a carrier (50) movable relative to the base (30),
at least one magnetic bearing (10, 100, 200) for generating a bearing or holding force (Hv, Hh) between the base (30) and the carrier (50), wherein the carrier (50) is contactlessly supported on the base (30) via the magnetic bearing (10, 100, 200),
at least one drive (40; 140) contactlessly acting between the base (30) and the carrier (50) for a displacement of the carrier (50) along the base (30) in at least one transport direction (T),
wherein the drive (40; 140) comprises a linear motor (38) with at least one slider (41; 141) and one stator (43; 143), which are arranged on the base (30) and on the carrier (50) and which, aside from a displacement force (V) acting along the transport direction (T), are configured to create a counter-force (G) between the base (30) and the carrier (50) which counteracts the bearing or holding force (Hv, Hh).

2. The device according to claim 1, wherein the at least one magnetic bearing (10, 100, 200) is configured as an actively controllable magnetic bearing (10, 100, 200) and comprises an electrically controllable electromagnet (12; 112) interacting magnetically with a counter-piece (18; 118) as well as a distance sensor (20, 120) and an electronic unit (15; 115) coupled therewith and configured to adjust a predetermined relative position of the base (30) and the carrier (50).

3. The device according to any one of the preceding claims, wherein at least one magnetic bearing (10) is configured as a vertical magnetic bearing (10) for generating a vertical holding force (Hv) counteracting the weight force of the carrier (50).

4. The device according to any one of the preceding claims, wherein at least one magnetic bearing (100, 200) is configured as a horizontal magnetic bearing for generating a holding force (Hh) acting horizontally between the base (30) and the carrier (50).

5. The device according to claim 4, wherein the horizontal magnetic bearing (100) comprises at least one electromagnet (112) arranged on the base (30) or on the carrier (50), which cooperates with a counter-piece (118) arranged on the carrier (50) or on the base (30) for the displacement of the carrier (50) in the transverse direction (Q).

6. The device according to claim 5, wherein the counter-piece (118) cooperating with the horizontal magnetic bearing (100) comprises at least one row of permanent magnets (118a, 118b) poled in an alternating manner and arranged on the carrier (50) or on the base (30), which permanent magnets are spaced apart from one another in a transverse direction (Q) obliquely or normal to the transport direction (T).

7. The device according to any one of claims 4 to 6, wherein the horizontal magnetic bearing (100, 200) interacts magnetically with an upper side (51) or an underside (53) of the carrier (50).

8. The device according to any one of the preceding claims, wherein the at least one magnetic bearing (10, 100, 200) and the drive (40; 140) interact magnetically with mutually opposite sides (51, 53, 55, 57) of the carrier (50).

9. The device according to any one of the preceding claims, wherein the base (30) comprises a plurality of magnetic bearings (10, 100, 200) spaced apart from one another in the transport direction (T) or in the transverse direction (Q), which magnetic bearings successively enter magnetically into an operative connection with at least one counter-piece (18; 118; 218) arranged on the carrier (50) for moving the carrier (50) along the base (30) in the transport direction (T) or in the transverse direction (Q).

10. The device according to any one of the preceding claims, wherein the base (30) comprises at least two transport paths (31; 131) running normal or obliquely to one another in the transport direction (T) and in the transverse direction (Q), with a plurality of magnetic bearings (10, 100, 200) in each case, wherein the transport paths (31; 131) adjoin one another in an intersection region (32).

11. The device according to claim 10, wherein at least two differently aligned sliders (41; 141) or stators (43; 143) of two drives (40; 140) are arranged on the carrier (50), one whereof is configured for moving the carrier (50) relative to the base (30) in the transport direction (T) and the other whereof is configured for moving the carrier (50) relative to the base (30) in the transverse direction (Q).

12. The device according to any one of preceding claim 10 or 11, wherein at least two sliders (41, 141) or stators (43, 143) aligned in parallel with one another are arranged on the carrier (50) at a predetermined minimum distance (DT, DQ) from one another in the transport direction (T) or in the transverse direction (Q).

13. The device according to any one of preceding claims 10 to 12, wherein each of the transport paths (31, 131) comprises stators (43; 143) or sliders (41; 141) spaced apart from one another in the transport direction (T) or in the transverse direction (Q), wherein the sliders (41; 141) or stators (43; 143) of one transport path (31) are arranged at a level of the intermediate spaces (3, 103) between the sliders (41; 141) or stators (43; 143) of the respective other transport path (131).

14. The device according to any one of preceding claims 11 to 13, wherein, in the intersection region (32), a pair, corresponding with each other, of sliders (41; 141) and stators (43; 143) of the two drives (40, 140) arranged on the carrier (50) and on the base (30), which pair belongs to one of the transport paths (31), can be activated in alternation with a pair of sliders and stators (41; 141, 43, 143) of the respective other transport path (131).

15. The device according to any one of preceding claims 10 to 14, wherein, in the intersection region (32), at least two magnetic bearings (10, 100) assigned to one of the two transport paths (131) can be activated, while two further magnetic bearings (10, 200) assigned to the respective other transport path (131) can be correspondingly deactivated.
